(19) United States
(12) Patent Application Publication
(10) Pub. No.: US 2026/0003121 A1
(43) Pub. Date: Jan. 1, 2026

(54) PHOTONIC INTEGRATED CIRCUITS WITH ALIGNED PHOTONIC DIES

(71) Applicant: Apple Inc., Cupertino, CA (US)

(72) Inventors: Jeffrey T. Hill, Los Altos, CA (US); Tomas Sarmiento, Mountain View, CA (US); Cheng-Yi Fang, San Jose, CA (US); Jeremy D. Witmer, San Jose, CA (US)

(21) Appl. No.: 19/087,269

(22) Filed: Mar. 21, 2025

Related U.S. Application Data
(60) Provisional application No. 63/665,855, filed on Jun. 28, 2024.

(51) Int. Cl. G02B 6/124; G02B 6/12; H01L 23/00

(52) U.S. Cl. CPC G02B 6/124; G02B 6/12004; H01L 24/16; H01L 2224/16147

(57) ABSTRACT

Various embodiments disclosed herein describe photonic integrated circuits having multiple photonic dies, and techniques for vertically aligning two photonic dies of a photonic integrated circuit. In some variations, a photonic die may include a cladding layer that is used to define a bottom surface of a waveguide layer. A portion of the cladding layer is used as an etch stop to define a top surface of a post, which may assist in vertically aligning the photonic die relative to an additional photonic die. Additionally or alternatively, a photonic die may include a ridge waveguide and multiple etch stop layers, of which a first etch stop layer defines a height of the ridge waveguide and a second etch stop layer defines a contact surface. The contact surface may contact a portion of an additional photonic die to help provide vertical alignment between the two photonic dies.

### CROSS-REFERENCE TO RELATED APPLICATIONS

This application is a nonprovisional and claims the benefit under 35 U.S.C. § 119(e) of U.S. Provisional Patent Application No. 63/665,855, filed Jun. 28, 2024, the contents of which are incorporated herein by reference as if fully disclosed herein.

### FIELD

This disclosure relates to alignment of photonic dies in a photonic integrated circuit. More particularly, this disclosure relates to use of etch stop layers to set the relative vertical alignment between two photonic dies.

### BACKGROUND

Photonic integrated circuits often integrate multiple different photonic dies, which may allow for different components of a photonic integrated circuit to be formed in different photonic dies. For example, a photonic integrated circuit may include a first photonic die formed from a first set of materials (e.g., using silicon-on-insulator technology), in which the first photonic die defines a first set of optical components for routing, modifying, and/or otherwise manipulating light carried by the photonic integrated circuit. It may be desirable for the photonic integrated circuit to include an additional component that cannot readily be manufactured using the materials and/or manufacturing techniques used to form the first photonic die. In these instances, a second photonic die may be formed from a second set of materials (e.g., one or more semiconductor materials) and/or using different manufacturing techniques, and may include a second set of optical components. In order to reduce optical losses as light is transmitted between the first and second photonic dies, it may be desirable to provide for precise alignment between the photonic dies of a photonic integrated circuit.

### SUMMARY

Described herein are photonic integrated circuits that include multiple, vertically aligned photonic dies. In some embodiments, a photonic integrated circuit includes a first photonic die and a second photonic die, where the first photonic die includes: a substrate, a first cladding layer supported by the substrate, and a waveguide layer positioned on the first cladding layer. The first photonic die defines a cavity that extends through the waveguide layer and the cladding layer, and the first photonic die defines a first post positioned within the cavity, such that a top surface of the cladding layer defines a top surface of the first post. The second photonic die includes: a ridge waveguide, a first etch stop layer defining a base of the ridge waveguide, and a second etch stop layer defining a first contact surface. The second photonic die is positioned at least partially inside of the cavity such that the first contact surface contacts the first post. This contact may act to vertically align a portion of the first photonic die relative to a portion of the second photonic die.

In some variations the photonic integrated circuit includes one or more layers vertically connecting the first contact surface to the first post. The one or more layers may include an anti-reflective coating. Additionally or alternatively, the one or more layers includes a set of metal layers. In some variations the first photonic die defines a second post positioned within the cavity and the second photonic die comprises a third etch stop layer that defines a second contact surface, such that the second photonic die is positioned at least partially inside of the cavity such that the second contact surface contacts the second post. In some of these variations, the top surface of the cladding layer defines a top surface of the second post.

In some variations, the second photonic die includes a set of quantum wells. In some of these variations, the first etch stop layer is positioned between the set of quantum wells and the second etch stop layer. In other variations, the set of quantum wells is positioned between the first etch stop layer and the second etch stop layer. In some variations, the second photonic die includes a grating structure and an additional etch stop layer that defines a position of the grating structure within the second photonic die.

Other embodiments are directed to a photonic integrated circuit that includes a first photonic die and a second photonic die, wherein the first photonic die includes a substrate, a first cladding layer supported by the substrate, and a waveguide layer positioned on the first cladding layer. The first photonic die defines a cavity that extends through the waveguide layer and the cladding layer, and the first photonic die defines a post positioned within the cavity, such that a top surface of the cladding layer defines a top surface of the post. The second photonic die includes an active region having a set of quantum wells, a cladding region surrounding the active region, a first etch stop layer that defines a position of a grating structure within the second photonic die, and a second etch stop layer defining a contact surface. The second photonic die is positioned at least partially inside of the cavity such that the contact surface contacts the post. This contact may act to vertically align a portion of the first photonic die relative to a portion of the second photonic die.

In some of these variations, the first etch stop layer is positioned between the active region and the second etch stop layer. Additionally or alternatively, the photonic integrated circuit includes one or more layers vertically connecting the contact surface to the post. In some of these variations, the one or more layers comprises an anti-reflective coating. Additionally or alternatively, the one or more layers comprises a set of metal layers.

Still other embodiments are directed to a photonic integrated circuit that includes a first photonic die and a second photonic die, wherein the first photonic die includes a substrate, a first cladding layer supported by the substrate, and a waveguide layer positioned on the first cladding layer. The first photonic die defines a cavity that extends through the waveguide layer and the cladding layer. The second photonic die includes a set of quantum wells, a ridge waveguide, a first etch stop layer defining a base of the ridge waveguide, and a second etch stop layer defining a set of contact surfaces. The set of quantum wells is positioned between the first etch stop layer and the second etch stop layer, and the second photonic die is positioned partially inside of the cavity such that the set of contact surfaces contact a portion of the first photonic die outside of the cavity. This contact may act to vertically align a portion of the first photonic die relative to a portion of the second photonic die. In some of these variations, the first photonic die comprises a second cladding layer positioned on the waveguide layer. The set of contact surfaces may contact a top surface of the second cladding layer. In some of these variations, the photonic integrated circuit may include an anti-reflective coating positioned on the top surface of the second cladding layer, such that the reflective coating is positioned between the contact surface and the second cladding layer.

In addition to the exemplary aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

FIGS. 1A and 1B depict top and cross-sectional side views, respectively, of a photonic integrated circuit that includes a first photonic die, where the first photonic die defines a cavity extending at least partially therethrough. FIGS. 1C and 1D show top and cross-sectional views, respectively, of a variation of the photonic integrated circuit of FIGS. 1A and 1B in which the photonic integrated circuit further includes a second photonic die bonded to the first photonic die.

FIGS. 2A-2D depict cross-sectional side views of variations of photonic integrated circuits that include a photonic die having multiple etch stop layers, such as described herein.

FIGS. 3A and 3B depict top and cross-sectional views, respectively, of a variation of a photonic integrated in a second photonic die is bonded to a first photonic die in a tilted orientation.

FIGS. 4 and 5 depict cross-sectional side views of variations of photonic integrated circuits that include a photonic die having multiple etch stop layers positioned on opposite sides of a set of quantum wells.

FIG. 6 depicts a cross-sectional side view of a variation of a photonic integrated circuit that include a photonic die having multiple etch stop layers and a buried heterostructure.

FIGS. 7A and 7B depict top views of variations of photonic integrated circuits that include multiple photonic dies that are each vertically aligned relative to a common photonic die using a corresponding post.

It should be understood that the proportions and dimensions (either relative or absolute) of the various features and elements (and collections and subsettings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

Directional terminology, such as “top”, “bottom”, “upper”, “lower”, “front”, “back”, “over”, “under”, “above”, “below”, “left”, “right”, “vertical”, “horizontal”, etc. is used with reference to the orientation of some of the components in some of the figures described below, and is not intended to be limiting. Because components in various embodiments can be positioned in a number of different orientations, directional terminology is used for purposes of illustration to demonstrate the relative orientation between components of the systems and devices described herein. The directional terminology is intended to be construed broadly, and therefore should not be interpreted to preclude components being oriented in different ways.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates to photonic integrated circuits having multiple photonic dies, and techniques for vertically aligning two photonic dies of a photonic integrated circuit. In some variations, a photonic die may include a cladding layer that is used to define a bottom surface of a waveguide layer. A portion of the cladding layer is used as an etch stop to define a top surface of a post, which may assist in vertically aligning the photonic die relative to an additional photonic die. Additionally or alternatively, a photonic die may include a ridge waveguide and multiple etch stop layers, of which a first etch stop layer defines a height of the ridge waveguide and a second etch stop layer defines a contact surface. The contact surface may contact a portion of an additional photonic die to help provide vertical alignment between the two photonic dies. In still other variations, a photonic die may include a buried heterostructure and multiple etch stop layers, of which a first etch stop layer defines a position of a grating structure and a second etch stop layer defines a contact surface for vertically aligning the photonic die relative to an additional photonic die.

As used herein, an “etch stop layer” refers to a layer within a photonic die that is formed from a first material that has a higher resistance to a particular etching process than a second material forming an additional layer that is in direct contact with the etch stop layer. Accordingly, when a portion of the additional layer is exposed to that etching process, that portion of the additional layer will be etched away until a surface of the etch stop layer is exposed. In effect, the etch stop layer will terminate the etching process without meaningfully removing the first material of the etch stop layer. An etch stop layer may provide precise termination of a particular etching process without requiring a specific time duration during which the photonic die is exposed to the etching process.

It should be appreciated that the material used to form a given etch stop layer of a photonic die as described herein may depend on the materials used to form that photonic die. For example, a layer of silicon dioxide may act as an etch stop layer when a layer of silicon is positioned in direct contact with the layer of silicon dioxide, as the silicon dioxide layer may exhibit higher resistance than silicon to certain etching processes. Semiconductor materials such as Indium Gallium Arsenide (InGaAs), Indium Gallium Arsenide Phosphide (InGaAsP), and Aluminum Gallium Arsenide (AlGaAs) may be used as etch stop layers in photonic dies formed from layers of semiconductor materials. It should be appreciated in instances where a given photonic die includes multiple etch stop layers, some or all of the etch stop layers may be formed from different materials depending on the design of the photonic die. Accordingly, different etching processes may be used to define features from different etch stop layers. For example, a first etching process may be used to remove material that is directly in contact with a first etch stop layer to define a first feature of a photonic die, and a second etching process may be used to remove material that is directly in contact with a second etch stop layer to define a second feature of the photonic die. Accordingly, the photonic dies described herein may accommodate a range of possible materials and associated etching processes to define the etch stop layers of these photonic dies.

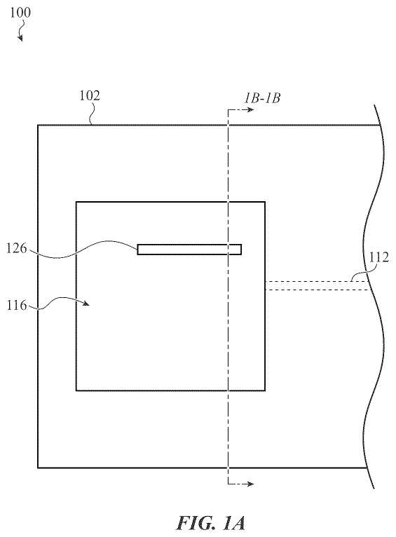

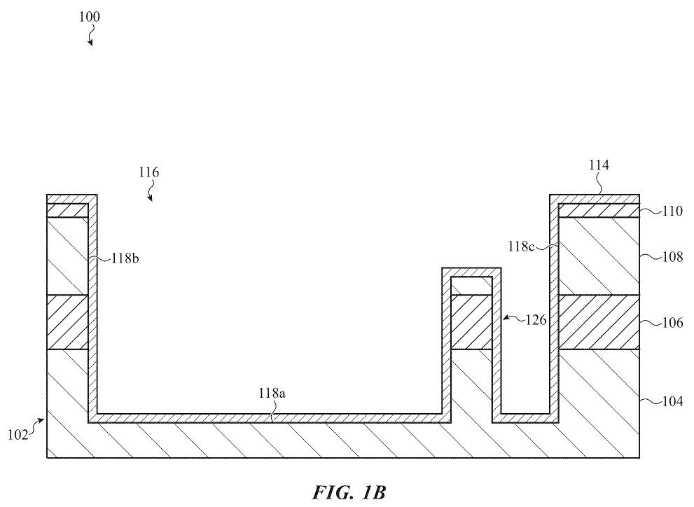

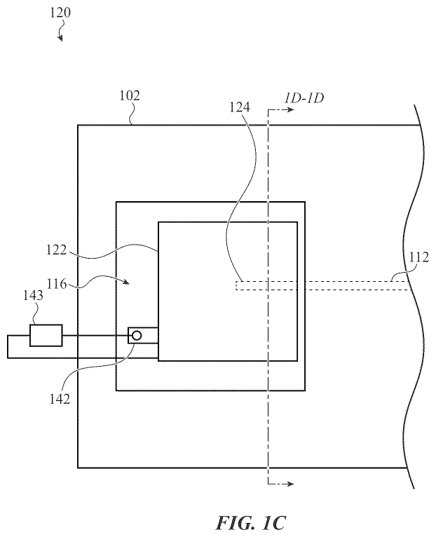

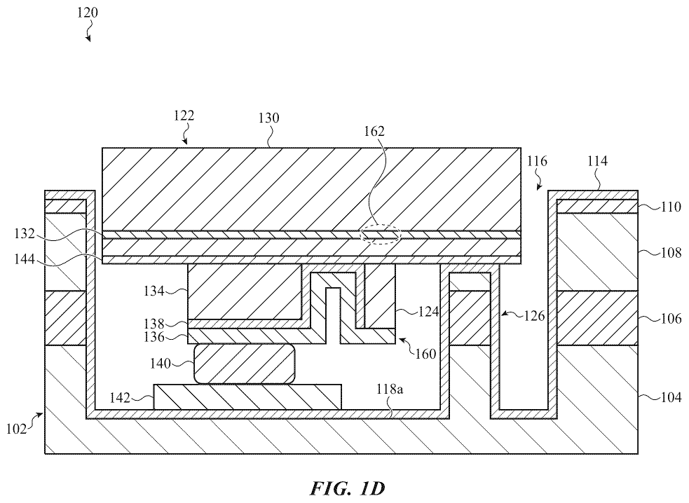

These and other embodiments are discussed with reference to FIGS. 1A-7B. However, those skilled in the art will readily appreciate that the detailed description given herein with respect to these figures is for explanatory purposes only and should not be construed as limiting.

A photonic integrated circuit may incorporate various optical and electrical components to help facilitate routing, modifying, and/or otherwise manipulating light carried by the photonic integrated circuit. Typically, the various components of a photonic integrated circuit are integrated into a first photonic die, which may include a layer stack that includes a substrate and a set of layers supported on the substrate. For example, FIG. 1A shows a top view and FIG. 1B shows a cross-sectional side view (taken along line 1B-1B) of a photonic integrated circuit 100 that includes a first photonic die 102. The first photonic die 102 may include a substrate 104 and a set of layers supported by the substrate 104. The set of layers includes a first cladding layer 106 and a waveguide layer 108 positioned on the first cladding layer 106, such that the first cladding layer 106 is positioned between the waveguide layer 108 and the substrate 104.

The waveguide layer 108 may be patterned or otherwise formed to define one or more optical components that carry light through the waveguide layer 108, such as one or more waveguides, splitters, couplers, or the like. The first cladding layer 106 may provide optical confinement to light travelling through the waveguide layer 108 (e.g., to light traveling through a first waveguide 112 defined in the waveguide layer 108). In some instances, one or more additional surfaces of the waveguide layer 108 may be covered with a second cladding layer 110, which may also provide optical confinement to light traveling through the waveguide layer 108. For example, the second cladding layer 110 may be positioned on the waveguide layer 108, such that a bottom surface of the waveguide layer 108 contacts a top surface of the first cladding layer 106 and a top surface of the waveguide layer 108 contacts a bottom surface of the second cladding layer 110. In regions where the waveguide layer 108 is patterned (e.g., to form one or more waveguides such as the first waveguide 112), the waveguide layer 108 may include one or more side surfaces. In some variations, the second cladding layer 110 may additionally contact one or more side surfaces of the waveguide layer 108. For example, the portion of the waveguide layer 108 forming the first waveguide 112 may include a first side surface and a second side surface (e.g., defining corresponding side surfaces of the first waveguide 112), and the second cladding layer 110 may contact these side surfaces to provide optical confinement to light traveling through the first waveguide 112.

The various layers of the first photonic die 102 may be formed from any suitable materials depending on the wavelength or wavelengths of light that will be carried by the waveguide layer 108. For example, in some variations, the first photonic die 102 is configured to carry one or more wavelengths of infrared light. In some of these variations, the waveguide layer 108 is formed from silicon, silicon nitride, silica, or the like, the first and second cladding layers 106, 110 are formed from one or more dielectric materials such as silicon dioxide, and the substrate 104 is formed from silicon. In some of these instances, the first photonic die 102 may be manufactured using silicon-on-insulator technology.

In some instances, one or more surfaces of the first photonic die 102 may be covered by a set of dielectric layers. In some instances, the set of dielectric layers may be configured as an anti-reflective coating, which may act to reduce reflections as light passes through the set of dielectric layers. This may help to reduce reflections as light enters or exits the first photonic die 102, such as through a facet of the waveguide layer 108. For example, the first photonic die 102 is shown in FIG. 1B as having an anti-reflective coating 114 deposited on or more surfaces of the first photonic die 102. It should be appreciated that the anti-reflective coating 114 may be formed as a single dielectric layer (e.g., single-layer quarter-wave coating) or as a plurality of dielectric layers (e.g., multi-layer coating).

To facilitate incorporation of additional components into the photonic integrated circuit 100, the first photonic die 102 is shaped to define a cavity 116 that extends at least partially through the first photonic die 102. In some instances, such as shown in FIG. 1B, the cavity 116 extends through each of the second cladding layer 110, the waveguide layer 108, and the first cladding layer 106, such that the cavity 116 extends to the substrate 104. In this way, the substrate 104 at least partially defines the cavity 116. Specifically, the cavity 116 may include a bottom wall 118a and a set of sidewalls. The number of sidewalls may depend on the shape of the cavity, and may include, for example, a first sidewall 118b and a second sidewall 118c as shown in FIG. 1B. The substrate 104 forms the bottom wall 118a of the cavity, and the first cladding layer 106 and the waveguide layer 108 may each at least partially form the set of sidewalls. In variations where the first photonic die 102 includes a second cladding layer 110, such as shown in FIG. 1B, the second cladding layer 110 may also at least partially form the set of sidewalls. In some variations, the substrate 104 may at least partially define the set of sidewalls. For example, in some instances the cavity may be shaped such that it extends partially through the substrate 104. In these instances, the substrate 104 may also form a corresponding portion of the set of sidewalls.

The photonic integrated circuit 100 may include one more additional photonic dies that are positioned at least partially inside the cavity 116. Positioning an additional photonic die at least partially inside of the cavity 116 to help position the additional photonic die relative to the first photonic die 102, which may facilitate the transfer of light between the photonic dies. For example, FIG. 1C shows a top view and FIG. 1D shows a cross-sectional side view (taken along line 1D-1D) of a variation of a photonic integrated circuit 120 that includes the first photonic die 102 of FIGS. 1A and 1B, as well as a second photonic die 122 that is connected to the first photonic die 102. The second photonic die 122 may be bonded to the first photonic die 102 such that a portion of the second photonic die 122 is positioned inside of the cavity 116 defined in the first photonic die 102. For example, the second photonic die 122 may be bonded to the first photonic die 102 in a flip-chip arrangement. With a portion of the second photonic die 122 positioned in the cavity 116, the second photonic die 122 may be bonded to the first photonic die 102 to connect the dies to each other.

It may be desirable to provide for a particular relative orientation between the first photonic die 102 and the second photonic die 122, such as to provide for precise relative placement and alignment between components of these dies. In the example of the photonic integrated circuit 120 shown in FIGS. 1C and 1D, the second photonic die 122 includes a waveguide (referred to herein as “second waveguide 124”). When the second photonic die 122 is bonded to the second photonic die 102, the first waveguide 112 and second waveguide 124 may be positioned relative to each other to allow for light to couple between the waveguides. Accordingly, it may be desirable to introduce mechanical structures configured to provide mechanical alignment between the first photonic die 102 and the second photonic die 122.

In some instances, a standoff structure (e.g., a post) may assist with vertical alignment of the dies. For example, in the variations shown in FIGS. 1A-1D, the first photonic die 102 may define one or more posts (such as post 126) positioned in the cavity 116. For example, the layer stack may form the one or more posts. Specifically, portions of the layers of the first photonic die 102 may be removed (e.g., via etching) to define the cavity 116, and this material may be selectively removed to leave the one or more posts. As the second photonic die 122 is flipped and inserted into the cavity 116, the one or more posts (such as post 126) may limit how far the second photonic die 122 can extend into the cavity 116, and thereby set the vertical positioning (e.g., the Z-axis positioning) of the second photonic die 122 in the cavity 116.

The configuration of the second photonic die 122 may impact how the second photonic die 122 is vertically aligned relative to the first photonic die 102. For example, the second photonic die 122 may include one or more active optical components configured to generate, measure, or manipulate light. For example, the one or more active optical components includes one or more lasers, each of which is operable to generate light (which may be coupled to the first photonic die 102). Additionally or alternatively, the one or more active optical components may include one or more photodetectors, electro-optic modulators, and/or optical amplifiers. Because the active optical components are formed as part of the second photonic die 122, they may be built using different materials and manufacturing process than those used to form the first photonic die 102.

For example, in the variation shown in FIGS. 1C and 1D, the second photonic die 122 includes an epitaxial structure 130 that includes various epitaxially-grown layers, including a set of quantum wells 132 (depicted in FIG. 1D as a single layer, though it should be appreciated that the set of quantum wells 132 may include multiple quantum wells). The second photonic die 122 includes an active optical component 160 that includes a ridge waveguide. Specifically, in the variation shown in FIGS. 1C and 1D, the second waveguide 124 is configured as a ridge waveguide, as is also referred to as “ridge waveguide 124.” The active optical component 160 is shown in FIG. 1D as a laser that is operable to generate light, though it should be appreciated that in other variations the active optical component may be a photodetector, an electro-optical modulator, an optical amplifier, or the like. When the active optical component 160 generates light 162, the ridge waveguide 124 may confine and direct light generated by the active optical component 160. Light may be emitted from the second photonic die 122 via the ridge waveguide 124 and may couple into the first photonic die 102 via the first waveguide 112.

To facilitate operation of the second photonic die 122, such as controlling one or more active optical components of the second photonic die 122, it may be necessary to route electrical signals (e.g., control signals, power signals, or the like) to and/or from the second photonic die 122. Accordingly, the second photonic die 122 may include one or more electrical contacts that may be used to electrically connect the second photonic die 122 to another portion of the photonic integrated circuit 120 (or to a portion of a larger optical system the includes the photonic integrated circuit 120). Specifically, the second photonic die 122 may be electrically connected to a driver 143 that can generate and/or receive electrical signals, which may allow the one or more drivers to operate the active optical components of the second photonic die 122.

For example, in instances when the second photonic die includes one or more lasers, the driver 143 may include a laser driver that is configured to control operation the lasers (e.g., to control the lasers to generate light, adjust a wavelength of light being generated by a laser, or the like). As one non-limiting example, the second photonic die 122 may include a contact ridge 134 that may facilitate an electrical connection between the second photonic die 122 and the first photonic die 102. Specifically, the contact ridge 134 may support an electrical contact layer (referred to herein as “laser electrical contact layer 136”) formed from an electrically conductive material (e.g., gold, copper, aluminum, or the like). The laser electrical contact layer 136 may be electrically coupled to a top surface of the ridge waveguide 124 to allow current to be supplied to the ridge waveguide 124 to facilitate generating light. The second photonic die 122 may further include an insulating layer 138 between the laser electrical contact layer 136 and other portions of the epitaxial structure 130 (such as one or both lateral sides of the ridge waveguide 124) to electrically insulate the laser electrical contact layer 136 from other portions of the epitaxial structure 130. It should be appreciated that any surfaces of the second photonic die may be coated with an insulating layer such as insulating layer 138, which may act to passivate the epitaxial structure 130 and thereby shield the epitaxial structure 130 from the surrounding environment.

For example, in order to receive power, the laser electrical contact layer 136 may be electrically connected to the driver 143. While shown in FIG. 1C as being positioned separately from the first photonic die 102, the driver 143 may be positioned in any suitable location within the photonic integrated circuit 120 or an optical system incorporating the photonic integrated circuit 120 as may be desired. Because the laser electrical contact layer 136 is positioned inside of the cavity 116 when the second photonic die 122 is flipped and inserted into the cavity 116, it may be difficult to facilitate electrical contact between the laser electrical contact layer 136 and the driver 143.

Accordingly, to make an electrical connection to the driver 143, the laser electrical contact layer 136 may be electrically connected to a corresponding electrical contact layer (referred to herein as “cavity electrical contact layer 142”) that is formed on, either directly or indirectly, the bottom wall 118a of the cavity 116. For example, a solder bump 140 (which may represent a single solder bump or multiple solder bumps) may electrically connect the laser electrical contact layer 136 to the cavity electrical contact layer 142. The solder bump 140 may be heated during assembly to temporarily melt the solder bump 140. When the solder of the solder bump 140 cools, the solder bump 140 may bond the second photonic die 122 to the first photonic die 102. The solder bump 140 may represent any electrically conductive material that is used to bond two components, including, but not limited to, bumps made from gold, conductive epoxy, copper, or the like. The electrical connection between the laser electrical contact layer 136 and the cavity electrical contact layer 142 may allow for current to be passed from the driver 143 to the second photonic die 122 to help power the active optical component 160 of the second photonic die 122. Specifically, the cavity electrical contact layer 142 electrically connects the driver 143 to the laser electrical contact layer 136, such that current passes through cavity electrical contact layer 142 as it passes between the driver 143 and the laser electrical contact layer 136. The active optical component 160 includes an additional electrical contact (not shown), such that current supplied by the driver flows through the ridge waveguide 124 and the set of quantum wells 132 to generate light 162. This additional electrical contact may, depending on the configuration of the first photonic die 102, be positioned on a common side of epitaxial structure 130 (e.g., coplanar) as the laser electrical contact layer 136 (e.g., using one or more vias to provide contact to an opposite side of the set of quantum wells) or may be positioned on opposite sides of epitaxial structure 130.

The dimensions of the ridge waveguide 124 may depend at least in part on the desired operating characteristics of the active optical component 160. To create the ridge waveguide 124, the second photonic die 122 may include a first etch stop layer 144. During manufacturing of the second photonic die 122, a portion of the epitaxial structure 130 may be selectively etched to define the ridge waveguide 124. The first etch stop layer 144 may act as an etch stop during this etching operation and may thereby form a base of the ridge waveguide 124, such that the ridge waveguide 124 extends away from the first etch stop layer 144. The first etch stop layer 144 is positioned within the epitaxial structure 130 to achieve a desired height of the ridge waveguide 124 (e.g., a distance between the base and the top surface of the ridge waveguide 124). In some instances, the first etch stop layer 144 may similarly form a base of the contact ridge 134, such that the contact ridge 134 and the ridge waveguide 124 have a common height.

In the variation of the photonic integrated circuit 120 shown in FIGS. 1C and 1D, a portion of the first etch stop layer 144 may act as a contact surface for vertically aligning the second photonic die 122 relative to the first photonic die 102. Specifically, the photonic integrated circuit 120 may be configured such that, when the second photonic die 122 is positioned to extend at least partially into the cavity 116, the first etch stop layer 144 contacts the post 126. In these instances, the height of the post 126 and the positioning on the first etch stop layer 144 within the epitaxial structure 130 will define the relative vertical positioning between the first photonic die 102 and the second photonic die 122. Since it may not be possible to change the relative positioning of the first etch stop layer 144 without adversely impacting the operation of the active optical component 160, the height of the post 126 may be selected in order to achieve a particular vertical alignment between the first photonic die 102 and the second photonic die 122.

Accordingly, in some variations, as shown in FIG. 1D, a portion of the waveguide layer 108 may form a top surface of the post 126. In these instances, the waveguide layer 108 may be partially removed to set a desired height of the post 126, which may be done using a time-based etching of the waveguide layer 108. Time-based etching may have relatively large variability across a given photonic die and/or between different dies having the same desired configuration. Additionally, certain waveguide materials (e.g., silicon) may experience surface non-uniformities during time-based etched, which result in a post 126 having an uneven top surface. Overall, this may result in unintended coupling losses as light is transferred between the first photonic die 102 and the second photonic die 122. In instances where the photonic integrated circuit 120 includes multiple photonic dies that are vertically aligned relative to the first photonic die 102, this may require the creation of multiple posts having different heights (e.g., to accommodate different configurations of active optical components between different photonic dies), which may further complicate the manufacturing process used to form the first photonic die 102.

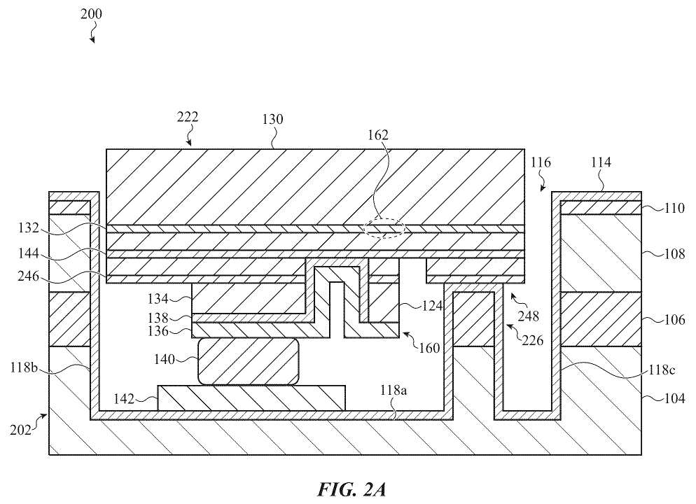

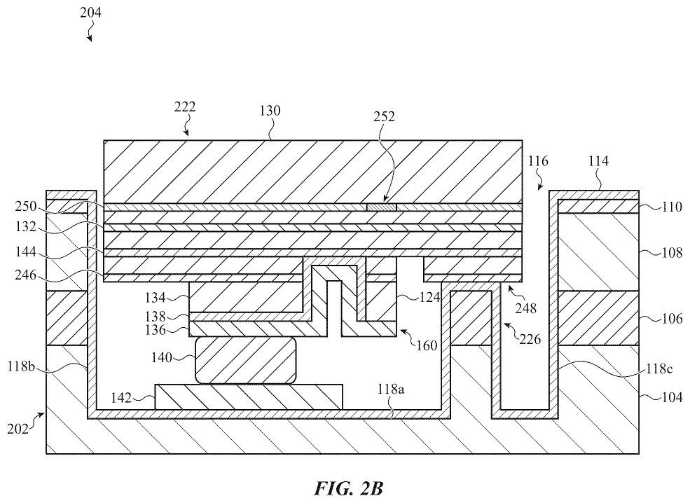

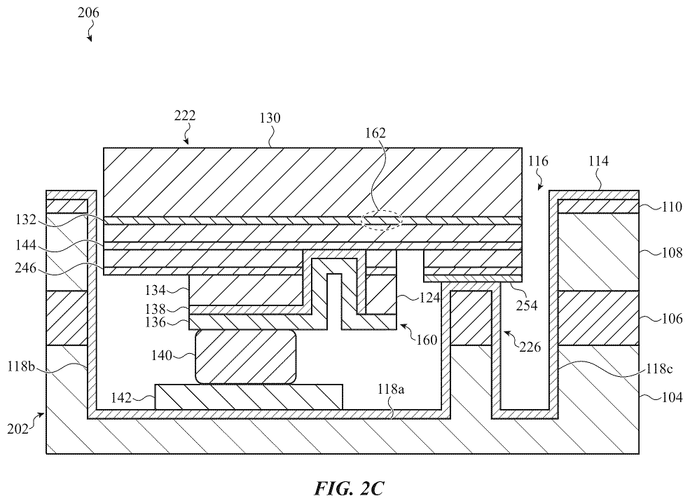

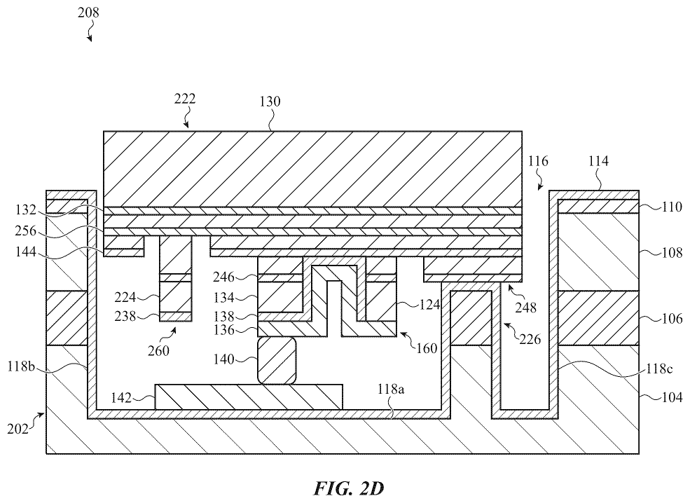

Accordingly, in some variations of the photonic integrated circuits described herein, the photonic integrated circuit may include a photonic die that includes an additional etch stop layer that is used for aligning the photonic die within the photonic integrated circuit. For example, FIG. 2A shows a cross-sectional side view of a variation of a photonic integrated circuit 120 that includes a first photonic die 202 and a second photonic die 222 that is connected to the first photonic die 202. The first photonic die 202 may be configured the same as the first photonic die 102 of FIGS. 1A-1D, except that the post 126 has been replaced by post 226.

In these variations, a top surface of first cladding layer 106 defines a top surface of the post 226. Specifically, depending on the etching process used to define the cavity 116 and the post 226, the first cladding layer 106 may act as an etch stop during formation of the post 226. In these instances, forming the post 226 may include etching through the waveguide layer 108 until a top surface of the first cladding layer 106 is exposed. In this way, the entire portion of the waveguide layer 108 positioned above the post 226 may be removed during formation of the post 226, and the post 226 is thereby formed from a portion of the substrate 104 and the first cladding layer 106. Because the first cladding layer 106 is used as an etch stop, the first cladding layer 106 may maintain its original height within the post 226. In other words, the height of a portion of the first cladding layer 106 within the post 226 may be the same the height of surrounding portions of the first cladding layer 106 that form the sidewalls of the cavity 116 (e.g., the first sidewall 118b and the second sidewall 118c shown in FIG. 2A). Because the overall height of the post 226 is the distance between the bottom surface 118a of the cavity and the top surface of the first cladding layer 106, the height of the post 226 depends on the depth of the cavity 116.

By using the first cladding layer 106 as an etch stop, the height of the post 226 may be accurately controlled and may have smaller variation from unit to unit as compared to the photonic integrated circuit 120 of FIGS. 1C and 1D. When the second photonic die 222 is bonded to the first photonic die 202, such that a portion of the second photonic die 222 is positioned inside of the cavity 116 defined in the first photonic die 202, a portion of the second photonic die 222 may contact the post 226. In the variation shown in FIG. 2A, the second photonic die 222 may be configured the same as the second photonic die 122 of FIGS. 1C and 1D, except that the second photonic die 222 further includes a second etch stop layer 246. In these instances, a portion of the second etch stop layer 246 may form a contact surface 248 of the second photonic die 222. When the second photonic die 222 is bonded to the first photonic die 202, the contact surface 248 may contact the post 226 and thereby set a vertical alignment between the first photonic die 202 and the second photonic die 222.

By using the second etch stop layer 246 for vertical alignment of the second photonic die 222, there may be greater flexibility in placing the first etch stop layer 144 within the epitaxial structure 130. Accordingly, the first etch stop layer 144 may be positioned in the epitaxial structure 130 at a first height and the second etch stop layer 246 may be positioned in the epitaxial structure 130 at a second height. In the variation shown in FIG. 2A, the first etch stop layer 144 is positioned between the second etch stop layer 246 and the set of quantum wells 132. The first height may be selected to achieve a desired height of the ridge waveguide 124. During a first etching operation, a first portion of the epitaxial structure 130 may be etched to the first etch stop layer 144 and thereby define a base of the ridge waveguide 124. The second height may be selected to achieve a desired distance between the contact surface 248 and the set of quantum wells 132. During a second etching operation (which may be performed in any suitable order relative to the first etching operation), a second portion of the epitaxial structure 130 may be etched to the second etch stop layer 246 and thereby define the contact surface 248.

In some variations, the second photonic die 222 may include one or more additional etch stop layers. For example, FIG. 2B shows a variation of a photonic integrated circuit 204 that is configured and labeled the same as the photonic integrated circuit 200 of FIG. 2A, except that the second photonic die 222 includes three etch stop layers. Specifically, the second photonic die 222 includes the first etch stop layer 144, the second etch stop layer 246, and a third etch stop layer 250. In some variations, such as shown in FIG. 2B, the third etch stop layer 250 may be positioned within the epitaxial stack at a third height such that the set of quantum wells 132 is positioned between the first etch stop layer 144 and the third etch stop layer 250. In some of these variations, the third etch stop layer 250 may be used to define the position of a grating structure 252 within the epitaxial structure 130. Specifically, the third etch stop layer 250 may be patterned to define the grating structure 252 or the grating structure 252 may be formed on the third etch stop layer 250. The grating structure 252 may act to reflect light traveling within the ridge waveguide 124. For example, in instances in which the active optical component 160 is a laser, such as a distributed feedback laser or a distributed Bragg reflector laser, the grating structure 252 may act to narrow and/or stabilize an emission wavelength generated by the laser. It should also be appreciated that, in some variations, one or more other etch stop layers of the second photonic dies described herein, such as those described herein with respect to FIGS. 2A-5, may additionally or alternatively be used to define the position of a grating structure within an epitaxial structure.

Although the second etch stop layer 246 and the post 226 may define the relative vertical positioning between the first photonic die 202 and the second photonic die 222, it should be appreciated that these components need not be in direct contact with each other. For example, in some variations the contact surface 248 may indirectly contact the post 226 via one or more intervening layers that are separate from the epitaxial structure 130 of the second photonic die 222 and the set of layers (e.g., the first cladding layer 106, the waveguide layer 108, and the second cladding layer 108) supported by the substrate 104 of the first photonic die 102. These intervening layers may be deposited on the contact surface 248 and/or the post 226. In these variations, the intervening layers may connect the contact surface 248 to the post 226 along the vertical direction and thus contribute to the vertical alignment between the first photonic die 202 and the second photonic die 222. The second height (e.g., with which the second etch stop layer 246 is positioned within the epitaxial structure 130) may be selected to account for the thickness of any intervening layers.

For example, in the variations of the photonic integrated circuits 200 and 204 shown in FIGS. 2A and 2B, respectively, the anti-reflective coating 114 may be deposited on a top surface of the post 226 (e.g., on a top surface of the first cladding layer 106). In these variations, the anti-reflective coating 114 may separate the contact surface 248 and the top surface of the post 226, such that the anti-reflective coating 114 connects the contact surface 248 to the post 226. FIG. 2C shows another example of a photonic integrated circuit 206 that is configured and labeled the same as the photonic integrated circuit 200 of FIG. 2A, except that the photonic integrated circuit 200 includes an additional set of layers 254 positioned between the contact surface 248 and the post 226. While shown as a single layer, it should be appreciated that the set of layers 254 may include multiple layers. For example, in some variations the set of layers 254 may act to provide an electrical connection between the first photonic die 202 and the second photonic die 222. In these variations, the set of layers 254 may include a set of metal layers that includes a first metal layer deposited on the contact surface 248 and a second metal layer deposited on the post 226 (e.g., deposited directly on the top surface of the first cladding layer 106, on top of another layer, such as the anti-reflective coating 114 that is deposited on the top surface of the first cladding layer 106). The first metal layer may contact the second metal layer to provide an electrical connection therebetween, and which may provide additional path (e.g., in addition to the connection between the laser electrical contact layer 136 and the cavity electrical contact layer 142) to transfer current between the first photonic die 202 and the second photonic die 222.

While the second photonic die 222 is shown in each of FIGS. 2A-2C as having a single ridge waveguide 124 as part of a single active optical component 160, it should be appreciated that the second photonic die 222 may include multiple active optical components that each include a corresponding ridge waveguide. In some variations, the first etch stop layer 144 may be used to define the height of multiple ridge waveguides of multiple respective active optical components. Additionally or alternatively, the second photonic die 222 may include one or more additional etch stops, each of which is used to define the height of one or more corresponding ridge waveguides. For example, FIG. 2D shows an example of a photonic integrated circuit 208 that has multiple active optical components, each of which having a ridge waveguide with a different height. Specifically, the photonic integrated circuit 208 may be configured and labeled the same as the photonic integrated circuit 200 of FIG. 2A, except that the second photonic die 222 includes a second active optical component 260, and the epitaxial stack 130 includes a third etch stop layer 256 that defines a height of a ridge waveguide 224 (also referred to herein as “second ridge waveguide 224”) of the second active optical component 260.

The third etch stop layer 256 may be positioned at a third height within the epitaxial stack 130, such that the third etch stop layer 256 is positioned between the second etch stop layer 246 and the set of quantum wells 132. The third height may be selected to achieve a desired height of the second ridge waveguide 224 of the second active optical component 260. Whereas portions of the epitaxial stack 130 may be etched during respective etching operations to define the first ridge waveguide 124 and the contact surface 248, a third portion of the epitaxial stack 130 may be etched to the third etch stop layer 256 during another etching operation and thereby define a base of the second ridge waveguide 224. In this way, the first active optical component 160 may have a first ridge waveguide 124 with a first height and the second active optical component 260 may have a second ridge waveguide 224 with a second height different than the first height. It should be appreciated that the photonic integrated circuit 208 of FIG. 2D may include any of the components of the photonic integrated circuit 204 of FIG. 2B (e.g., the etch stop layer 250 and the associated grating structure 252) and/or the photonic integrated circuit 206 of FIG. 2C (e.g., the set of layers 254 vertically positioned between the contact surface 248 and the post 226).

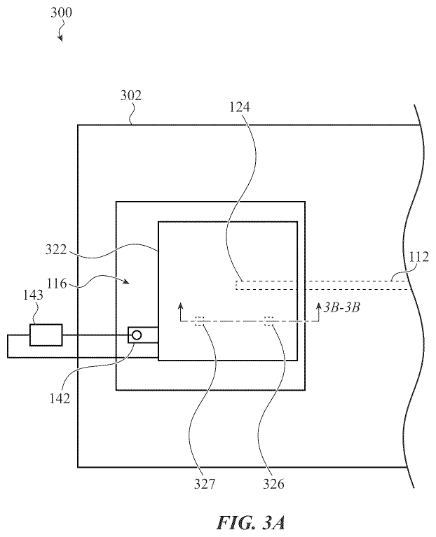

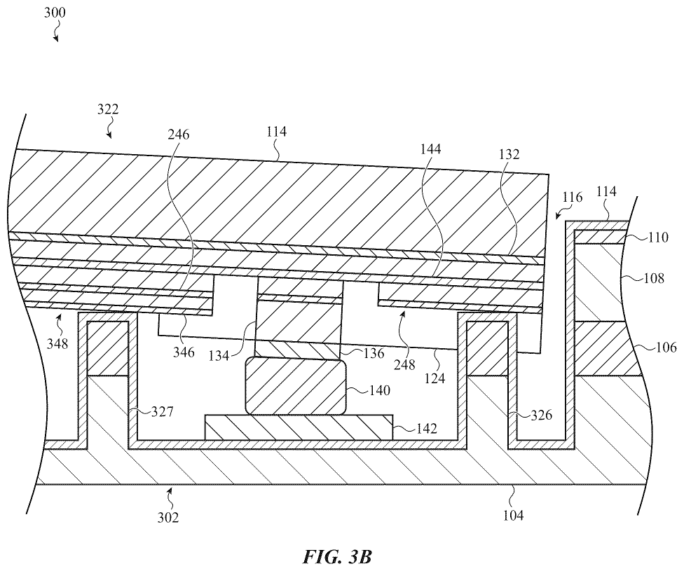

In some variations, a photonic die may include multiple contact surfaces that are positioned at different heights, which may allow the photonic die to achieve a predetermined tilt relative to another photonic die. For example, FIG. 3A shows a top view and FIG. 3B shows a cross-sectional side view (taken along line 3B-3B) of a variation of a photonic integrated circuit 300 that includes a first photonic die 302 and a second photonic die 322 that is connected to the first photonic die 302. The first photonic die 302 may be configured the same as the first photonic die 102 of FIGS. 1A-1D, except that the post 126 has been replaced by a first post 326 and a second post 327. In the variation shown in FIGS. 3A and 3B, the first post 326 and the second post 327 may each be formed such that a top surface of the cladding layer 106 defines a respective top surface of each of the first post 326 and the second post 327. Accordingly, the first post 326 and the second post 327 have coplanar top surfaces and may be formed using a common etching step if so desired. If the cavity 116 has the same depth around the first post 326 and the second post 327, the first post 326 and the second post 327 may also have a common height.

The second photonic die 322 may be configured the same as the second photonic die 222 of FIG. 2A, except that the second photonic die 322 further includes a third etch stop layer 346. In these instances, the first etch stop layer 144 may define a base of the ridge waveguide 124, a portion of the second etch stop layer 246 may form a first contact surface 248, and a portion of the third etch stop layer 346 may form a second contact surface 348. The third etch stop layer 346 may positioned at a third height within the epitaxial stack 130, and a portion of the epitaxial structure 130 may be etched to the third etch stop layer 346 and thereby define the second contact surface. Accordingly, the first contact surface 248 and the second contact surface 348 may be positioned at different heights within the epitaxial structure 130.

When the second photonic die 322 is inserted into the cavity 116 along a vertical direction and is bonded to the first photonic die 302, the first contact surface 248 may contact the first post 326 and the second contact surface 348 may contact the second post 327. Because the first post 326 and the second post 327 have a common height within the cavity 116 and the first contact surface 248 and the second contact surface 348 are positioned at different heights within the epitaxial stack 130, this may result in the second photonic die 322 being tilted relative to the first photonic die 302. The second photonic die 322 is tilted in FIG. 3B such that the ridge waveguide is rotated along a pitch axis relative to the first photonic die 302. Additionally or alternatively, the second photonic die 322 may tilted such that the ridge waveguide is rotated along a roll axis relative to the first photonic die 302. Changing the pitch and/or roll angle of the second photonic die 322 may help reduce back-reflections that may occur as light is transmitted between the photonic dies and/or may impact the transmission of polarized light between the photonic dies. It should be appreciated that the photonic integrated circuit 300 may include any of the features described herein with respect to the photonic integrated circuits of FIGS. 2A-2D.

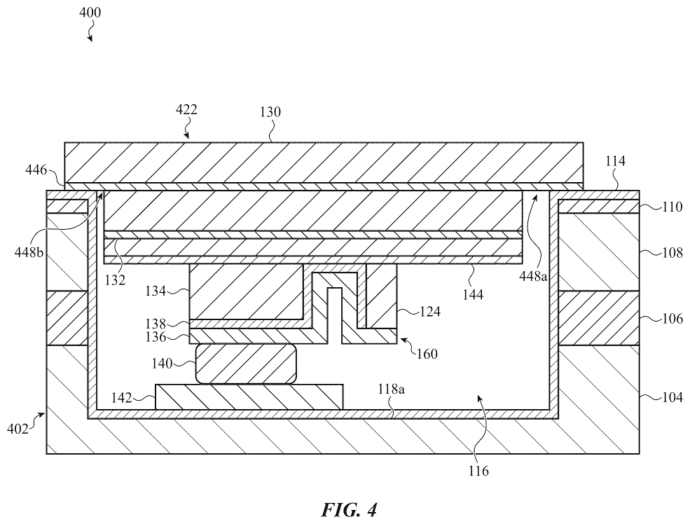

In the variations of the photonic integrated circuits described herein with respect to FIGS. 2A-2D and 3A-3B, the photonic integrated circuit includes a second photonic die in which a first etch stop that defines the height of a ridge waveguide and a second etch stop that defines a contact surface are positioned on a common side relative to a set of quantum wells. In other variations, the second photonic die may be configured such that the set of quantum wells is positioned between the first etch stop and the second etch stop. For example, FIG. 4 shows a cross-sectional side view of a variation of a photonic integrated circuit 400 that includes a first photonic die 402 and a second photonic die 422 that is connected to the first photonic die 402. The first photonic die 402 may be configured and labeled the same as the first photonic die 102 of FIGS. 1A-1D, except that the first photonic die 402 does not include the post 126. It should be appreciated that, if so, desired, the first photonic die 402 may still include one or more posts.

The second photonic die 422 may be configured and labeled the same as the second photonic die 122 of FIGS. 1C and 1D, except that the second photonic die 422 further includes a second etch stop layer 446. The second etch stop layer 446 is positioned at a second height within the epitaxial structure 130 such that the set of quantum wells 132 is positioned between the first etch stop layer 144 and the second etch stop layer 446. In these instances, a first portion of the epitaxial structure 130 may be etched to the first etch stop layer 144 to define the ridge waveguide 124, and a second portion of the epitaxial structure may be etched to the second etch stop layer 446 to define a set of contact surfaces 448a-448b of the second photonic die 422. The second photonic die 422 may be partially inserted into the cavity 116 to bond the second photonic die 422 to the first photonic die 402. When the second photonic die 422 is inserted into the cavity 116, the ridge waveguide 124 and the set of quantum wells 132 are positioned within the cavity 116, and the set of contact surfaces 448a-448b may remain outside of the cavity 116.

Specifically, the set of contact surfaces 448a-448b may contact a portion of the first photonic die 402 outside of the cavity 116 (e.g., a top surface of one the set of layers supported by the substrate 104 of the first photonic die 402), which limits how far the second photonic die 422 may be inserted into the cavity 116 and thereby provide vertical alignment between the first photonic die 402 and the second photonic die 422. For example, in the variation shown in FIG. 4, the set of contact surfaces 448a-448b may contact a top surface of the second cladding layer 110. In other variations, such as when the first photonic die 402 does not include a second cladding layer 110 or a portion of the second cladding layer 110 adjacent to the cavity 116 has been removed, the set of contact surfaces 448a-448b may contact the waveguide layer 108. It should be appreciated that one or more additional layers (e.g., the anti-reflective coating 114) may be deposited on the first photonic die 402 and/or the second photonic die 422 between the set of contact surfaces 448a-448b and the set of layers forming the first photonic die 402. For example, an adhesive may be positioned between the set of contact surfaces 448a-448b and the first photonic die 402 to help bond the first photonic die 402 to the second photonic die 422. Additionally or alternatively, the solder bump 140 between the laser electrical contact layer 136 and the cavity electrical contact layer 142 may help bond the first photonic die 402 to the second photonic die 422 as described in more detail herein.

While shown in FIG. 4 as having two contact surfaces (e.g., a first contact surface 448a and a second contact surface 448b), the set of contact surfaces 448a-448b may include a single contact surface or three or more separate contact surfaces. In some variations, a single contact surface may surround the cavity. In these instances, the contact between the contact surface and the first photonic die 402 may act to create a seal that encloses the cavity 116. Accordingly, the first photonic die 402 and the second photonic die 422 may collectively provide a hermetically sealed cavity 116, which may reduce the likelihood that moisture or other contaminants interact with portions of the second photonic die 422 (e.g., ridge waveguide 124) that are positioned within the cavity 116. In some variations, one or more additional metal layers may be positioned between the contact surface and the first photonic die 402 to facilitate metal-on-metal bonding. Additionally or alternatively, an epoxy may be applied to one or more portions of the first photonic die 402 and/or the second photonic die 422 to help seal off the cavity 116. It should also be appreciated that the second photonic die may include any of the additional etch stop layers as described herein, such as the etch stop layer 250 of FIG. 2B (which may be used to define the position of a grating structure of the second photonic die 422) and/or the etch stop layer 256 of FIG. 2D (which may be used to define the height of a second ridge waveguide of a second active optical component).

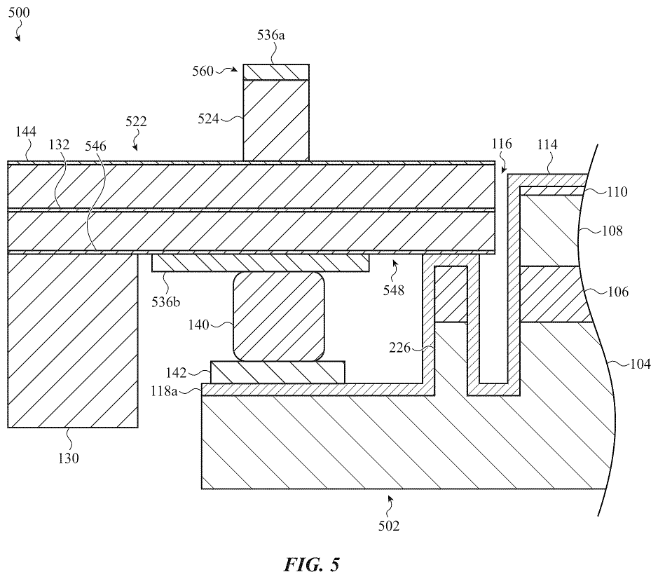

FIG. 5 shows a cross-sectional side view of another variation of a photonic integrated circuit 500 that includes a first photonic die 502 and a second photonic die 522 that is connected to the first photonic die 502. The first photonic die 502 may be configured and labeled the same as the first photonic die 202 of FIG. 2A, except that the cavity 116 extends to a lateral side of the first photonic die 202. In these instances, the set of sidewalls that define the lateral boundaries of the cavity may not fully enclose the cavity 116, such that cavity is open to a lateral side of the first photonic die 202.

The second photonic die 522 includes an epitaxial structure 130 that includes various epitaxially-grown layers, including a set of quantum wells 132. The second photonic die 522 includes an active optical component 560 that includes a ridge waveguide 524, such as described in more detail herein. The second photonic die includes a first etch stop layer 144, such as described in more detail herein, which may form a base of the ridge waveguide 524 and thereby define a height of the ridge waveguide 524. The second photonic die 522 further includes a second etch stop layer 546, such that a portion of the second etch stop layer 546 forms a contact surface 548 of the second photonic die 522. When the second photonic die 522 is bonded to the first photonic die 502, the contact surface 548 may contact the post 226 and thereby set a vertical alignment between the first photonic die 502 and the second photonic die 522.

The first etch stop layer 144 may be positioned in the epitaxial structure 130 at a first height and the second etch stop layer 546 may be positioned in the epitaxial structure 130 at a second height, such that the set of quantum wells 132 is positioned between the first etch stop layer 144 and the second etch stop layer 546. In these variations, the ridge waveguide 524 may extend from the first etch stop layer 144 in a direction away from a bottom wall 118a of the cavity 116. In some of these variations, the ridge waveguide 524 may be at least partially positioned outside of the cavity 116. In some variations, the first etch stop layer 144 may also define a height of a contact ridge (not shown), such as the contract ridge 134 described in more detail herein.

The active optical component 560 may include a set of electrical contact layers 536a-536b that may be used to route current through the ridge waveguide 524 and set of quantum wells 132. The set of electrical contact layers 536a-536b includes a first electrical contact layer 536a and a second electrical contact layer 536b. The first electrical contact layer 536a may be positioned in electrical contact with a top surface of the ridge waveguide 524. The second electrical contact layer 536b may be positioned in electrical contact with the contact surface 548. The second electrical contact layer 536b may be electrically and physically connected to a cavity electrical contact layer 142 via a solder bump 140, such as described in more detail herein with respect to the photonic integrated circuit 120 of FIGS. 1C and 1D.

Depending on the size of the layers needed to form the epitaxial structure 130 of the second photonic die 522, a portion of the second photonic die 522 may extend laterally outside of the cavity 116, such as shown in FIG. 5. In these instances, a portion of the epitaxial structure 130 that is positioned outside of the cavity 116, may extend vertically past the bottom wall 118a of the cavity 116.

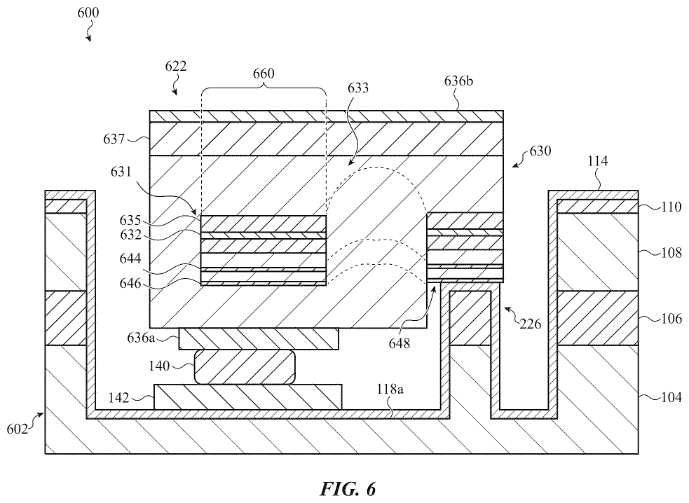

It should be appreciated that the second photonic dies of the photonic integrated circuits described herein with respect to FIGS. 2A-5 may applied to epitaxial structures having either n-on-p configurations (e.g., where the ridge waveguide is formed from an n-type cladding and the epitaxial structure includes a p-type cladding on an opposite side of the quantum wells) or a p-on-n configurations (e.g., where the ridge waveguide is formed from a p-type cladding and the epitaxial structure includes an n-type cladding on an opposite side of the quantum wells), as may be desired. Additionally, the principles described herein with respect to the photonic integrated circuits of FIGS. 2A-5 may also be applied to active optical components that utilize buried heterostructures, such as a buried heterostructure laser. In these variations, a photonic die may include multiple etch stop layers, such that one of the etch stop layers may be positioned to achieve a particular vertical alignment with another photonic die. For example, FIG. 6 shows a cross-sectional side view of another variation of a photonic integrated circuit 600 that includes a first photonic die 602 and a second photonic die 622 that is connected to the first photonic die 602. The first photonic die 602 may be configured and labeled the same as the first photonic die 202 of FIG. 2A.

The second photonic die 622 is configured to include an active optical component 660 that utilizes a buried heterostructure. Specifically, the second photonic die 622 includes an epitaxial structure 630 that includes an active region 631 that is surrounded by a cladding region 633. The active region 631 may include a set of quantum wells 632 that may be positioned between waveguide layers 635. Light, such as light generated or received by the active optical component 660, may be confined within the active region 631. The cladding region 633 may be supported by a substrate 637 and may include a single cladding material or multiple layers formed from different cladding materials. The active optical component 660 may further include a set of electrical contact layers 636a-636b that includes a first electrical contact layer 636a and a second electrical contact layer 636b. In the variation shown in FIG. 6, the first electrical contact layer 636a and the second electrical contact layer 636b are positioned on opposite sides of the epitaxial structure 630. The first electrical contact layer 636a may be electrically and physically connected to a cavity electrical contact layer 142 via a solder bump 140, such as described in more detail herein with respect to the photonic integrated circuit 120 of FIGS. 1C and 1D.

The second photonic die 622 includes at least a first etch stop layer 644 and a second etch stop layer 646, each of which may be positioned in the cladding region 633 of the epitaxial structure 630. The first etch stop layer 644 may define a position of a grating structure of the active optical component 660 (e.g., the first etch stop layer 644 may be patterned to define the grating structure or the grating structure may be formed on the first etch stop layer 644), and a portion of the second etch stop layer 646 may define a contact surface 648. Specifically, a portion of the epitaxial structure 630 may be etched to expose a portion of the second etch stop layer 646 and thereby define the contact surface 648. When the second photonic die 622 is bonded to the first photonic die 602, the contact surface 648 may contact the post 226 and thereby set a vertical alignment between the first photonic die 602 and the second photonic die 622. It should be appreciated that the contact surface 648 may directly or indirectly (e.g., via one or more intervening layers such as the anti-reflective coating 114 positioned on the top surface of the second cladding layer 110) contact the post 226 along a vertical direction, such as described in more detail herein. Accordingly, by including multiple etch stop layers, the first etch stop layer 644 may be positioned in the epitaxial structure 630 at a first height that is selected based on a desired placement of the grating structure within the active optical component 600, and the second etch stop layer 646 may be positioned in the epitaxial structure 630 at a second height that is selected based on a desired vertical alignment between the first photonic die 602 and the second photonic die 622. In the variation shown in FIG. 6, the first etch stop layer 644 is positioned between the active region 631 and the second etch stop layer 646.

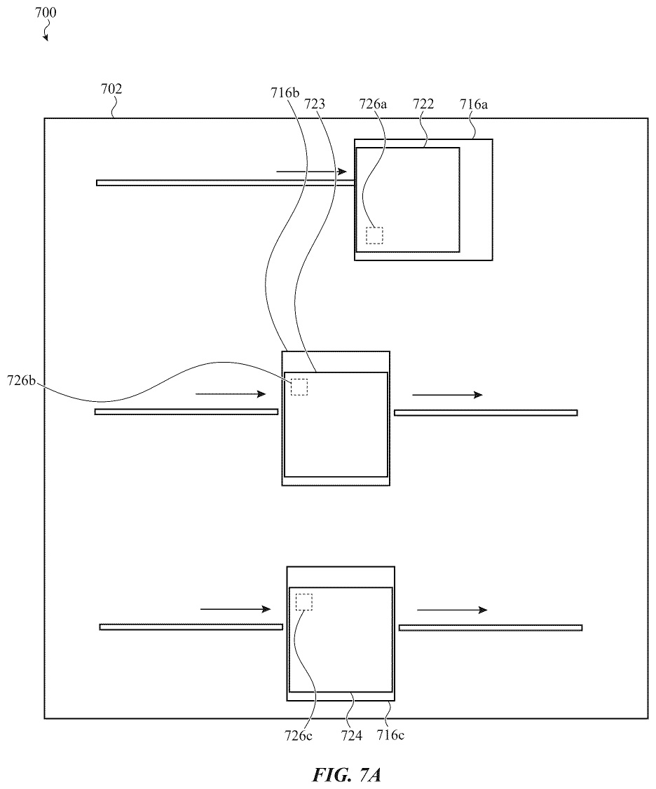

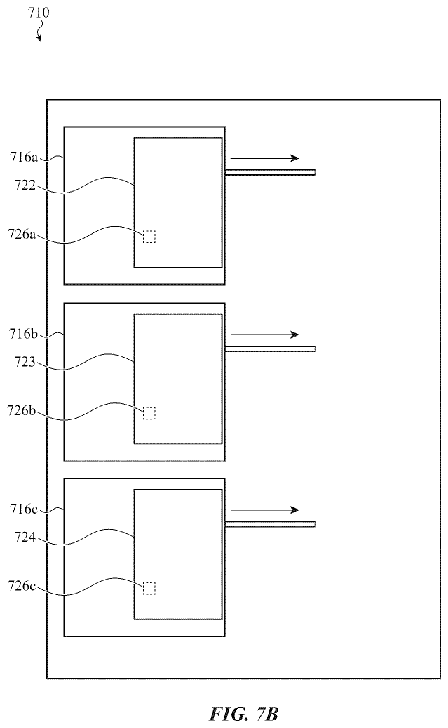

The use of a cladding layer as an etch stop may allow for a single photonic die to include multiple posts that have coplanar top surfaces. This may provide a common plane of reference for vertically aligning additional photonic dies relative to the photonic die. For example, FIG. 7A shows a top view of a variation of photonic integrated circuit 700 that includes a first photonic die 702. The first photonic die 702 may include a substrate, a first cladding layer, and a waveguide layer, such as described in more detail herein, wherein the first cladding layer is used as an etch stop to define a plurality of posts 726a-726c. In these instances, a top surface of the first cladding layer defines a corresponding top surface of each of the plurality of posts 726a-726c, such that the top surfaces of the plurality of posts 726a-726c are coplanar. While the plurality of posts 726a-726c are shown in FIG. 7A as having three posts (e.g., a first post 726a, a second post 726b, and a third post 726c), it should be appreciated that there may be more or fewer posts defined in this manner. Each of the plurality of posts 726a-726c is shown in FIG. 7A as being positioned in a separate cavity defined to extend at least partially through the first photonic die 702 (e.g., the first post 726a is positioned within a first cavity 716a, the second post 726b is positioned within a second cavity 716b, and the third post 726c is positioned with a third cavity 716c), though it should be appreciated that multiple posts of the plurality of posts 726a-726c may be positioned in a common cavity. In instances where different cavities have different depths, some or all of the plurality of posts 726a-726c may have different heights.

Each of the plurality of posts 726a-726c may be used to vertically align a plurality of photonic dies with the first photonic die 702. For example, in the variation shown in FIG. 7A, the first post 726a may vertically align a second photonic die 722 relative to the first photonic die 702, the second post 726b may vertically align a third photonic die 723 relative to the first photonic die 702, and the third post 726c may vertically align a fourth photonic die 724 relative to the first photonic die 702. Some or all of the additional photonic dies may include multiple etch stop layers, such as described herein with respect to FIGS. 2A-6. This may allow each additional photonic die to define a contact surface that is positioned at a height that, when placed in contact with a corresponding post of the plurality of posts 726a-726c, achieve a desired alignment between that photonic die and the first photonic die 702. This may simplify the processing of the first photonic die 702 as compared to instances in which the top surfaces of the plurality of posts are positioned at different heights within the first photonic die 702.

The plurality of posts 726a-726b may be used to vertically align a variety of active optical components relative to the first photonic die 702. For example, in the variation shown in FIG. 7A, the second photonic die 722 may include one or more active optical components that includes at least one photodetector, the third photonic die 723 may include one or more active optical components that includes at least one electro-optic modulator, and the fourth photonic die 724 may include one or more active optical components that includes at least one optical amplifiers. FIG. 7B shows a top view of another variation of a photonic integrated circuit 710, that is configured and labeled the same as the photonic integrated circuit 700 of FIG. 7A, except that each of the second photonic die 722, the third photonic die 723, and the fourth photonic die 724 includes one or more active optical components that includes at least laser. In these instances, the lasers of the different photonic dies may be configured to emit light having different properties (e.g., different wavelengths). It should be appreciated that these are just illustrative examples, and the principles described herein may be applied to any number and combination of photonic dies.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

What is claimed is:

1. A photonic integrated circuit, comprising:
a first photonic die comprising:
a substrate;
a first cladding layer supported by the substrate; and
a waveguide layer positioned on the first cladding layer, wherein:
the first photonic die defines a cavity that extends through the waveguide layer and the cladding layer; and
the first photonic die defines a first post positioned within the cavity, such that a top surface of the cladding layer defines a top surface of the first post; and
a second photonic die comprising:
a ridge waveguide;
a first etch stop layer defining a base of the ridge waveguide; and
a second etch stop layer defining a first contact surface;
wherein the second photonic die is positioned at least partially inside of the cavity such that the first contact surface contacts the first post.

2. The photonic integrated circuit of claim 1, comprising one or more layers vertically connecting the first contact surface to the first post.

3. The photonic integrated circuit of claim 2, wherein the one or more layers comprises an anti-reflective coating.

4. The photonic integrated circuit of claim 2, wherein the one or more layers comprises a set of metal layers.

5. The photonic integrated circuit of claim 1, wherein:
the first photonic die defines a second post positioned within the cavity;
the second photonic die comprises a third etch stop layer that defines a second contact surface; and
the second photonic die is positioned at least partially inside of the cavity such that the second contact surface contacts the second post.

6. The photonic integrated circuit of claim 5, wherein the top surface of the cladding layer defines a top surface of the second post.

7. The photonic integrated circuit of claim 1, wherein:
the second photonic die comprises a set of quantum wells.

8. The photonic integrated circuit of claim 7, wherein:
the first etch stop layer is positioned between the set of quantum wells and the second etch stop layer.

9. The photonic integrated circuit of claim 7, wherein:
the set of quantum wells is positioned between the first etch stop layer and the second etch stop layer.

10. The photonic integrated circuit claim 1, wherein:
the second photonic die comprises a grating structure; and
the second photonic die comprises an additional etch stop layer that defines a position of the grating structure within the second photonic die.

11. The photonic integrated circuit of claim 1, wherein:
the second photonic die comprises one or more active optical components.

12. A photonic integrated circuit, comprising:
a first photonic die comprising:
a substrate;
a first cladding layer supported by the substrate; and
a waveguide layer positioned on the first cladding layer, wherein:
the first photonic die defines a cavity that extends through the waveguide layer and the cladding layer; and
the first photonic die defines a post positioned within the cavity, such that a top surface of the cladding layer defines a top surface of the post; and
a second photonic die comprising:
an active region comprising a set of quantum wells;
a cladding region surrounding the active region;
a first etch stop layer that defines a position of a grating structure within the second photonic die; and
a second etch stop layer defining a contact surface, wherein:
the second photonic die is positioned at least partially inside of the cavity such that the contact surface contacts the post.

13. The photonic integrated circuit of claim 12, wherein the first etch stop layer is positioned between the active region and the second etch stop layer.

14. The photonic integrated circuit of claim 12, comprising one or more layers vertically connecting the contact surface to the post.

15. The photonic integrated circuit of claim 14, wherein the one or more layers comprises an anti-reflective coating.

16. The photonic integrated circuit of claim 14, wherein the one or more layers comprises a set of metal layers.

17. A photonic integrated circuit, comprising:
a first photonic die comprising:
a substrate;
a first cladding layer supported by the substrate; and
a waveguide layer positioned on the first cladding layer, wherein:
the first photonic die defines a cavity that extends through the waveguide layer and the cladding layer; and
a second photonic die comprising:
a set of quantum wells;
a ridge waveguide;
a first etch stop layer defining a base of the ridge waveguide; and
a second etch stop layer defining a set of contact surfaces, wherein:
the set of quantum wells is positioned between the first etch stop layer and the second etch stop layer; and
the second photonic die is positioned partially inside of the cavity such that the set of contact surfaces contact a portion of the first photonic die outside of the cavity.

18. The photonic integrated circuit of claim 17, wherein the first photonic die comprises a second cladding layer positioned on the waveguide layer.

19. The photonic integrated circuit of claim 18, wherein the set of contact surfaces contact a top surface of the second cladding layer.

20. The photonic integrated circuit of claim 18, further comprising an anti-reflective coating positioned on the top surface of the second cladding layer between the contact surface and the second cladding layer.
